(19) United States
(12) Patent Application Publication
(10) Pub. No.: US 2006/0067056 A1
(43) Pub. Date: Mar. 30, 2006

(54) Heat dissipating module

(75) Inventor: Chung-An Lin, Shindian City (TW)

Correspondence Address: BIRCH STEWART KOLASCH & BIRCH, PO BOX 747, FALLS CHURCH, VA, 22040-0747, US

(73) Assignee: VIA TECHNOLOGIES, INC.

(21) Appl. No.: 11/213,822

(22) Filed: Aug. 30, 2005

(30) Foreign Application Priority Data
Sep. 24, 2004 (TW) 093129135

(51) Int. Cl. H05K 7/20

(52) U.S. Cl. 361/709; 361/718; 165/104.33

(57) ABSTRACT

A heat dissipating module can fix a fan onto a heat sink rapidly and stably. The heat dissipating module includes a heat sink, a fan, a plurality of holding elements and a plurality of fixing elements. The heat sink has a plurality parallel of fins extended outward. The fan is disposed on the fins and has a plurality of fixing holes. The holding elements are respectively disposed on the two adjacent fins. The holding element includes a top portion and two side portions respectively extended from two corresponding sides of the top portion, and the top portion has at least one through hole. The fixing elements respectively thread through the fixing hole and the through hole in order, and the side portions of the holding element hold the fixing element between the two adjacent fins.

### BACKGROUND OF THE INVENTION

1. Field of Invention

The present invention relates to a heat dissipating module, and in particular, to a heat dissipating module with a plurality of holding elements to fix a fan onto a heat sink rapidly and stably.

2. Related Art

Due to rapid development of semiconductor device and process, semiconductor chips such as central processing unit (CPU) operate at a higher speed and have powerful functionality. However, the chip dissipates lots of heat during operation at the same time. In order to maintain the chip being normally operated within allowable temperature, a variety of heat dissipating modules are developed. The heat dissipating module is generally sequentially disposed a heat sink on the chip and a fan on the heat sink to dissipate the heat through the forced air convection.

As shown in FIG. 1, a conventional heat dissipating module 9 includes a heat sink 92 and a fan 94. The heat sink 92 has a plurality of screw holes 920 disposed at the bottom portion. The fan 94 is fixed on the heat sink 92 by a plurality of long screws 96 threading through the fan 94 and the fin 922 in order to respectively screw the screws 96 to the screw holes 920. However, lots of extra work to the heat sink including the process of forming the screw holes and the process of removing the fins on the screw holes are needed to perform. The higher the fin is, the longer the screw is needed. Thus, that leads a complicated fabrication and affects the support.

Some of prior arts apply a fastener to fix the fan under the heat sink. However, the fan fixed by this construction is easily shifted or separated from the heat sink caused by the shock or the vibration during transportation.

Some of prior arts dispose a fixing plate on the heat sink. The fan is screwed onto the fixing plate, then the periphery of the fixing plate is correspondingly screwed onto the peripheral fins of the heat sink. The construction needs thicker peripheral fins, and the fixing plate may affect air convection and may be loosed by the screw stripping.

It is therefore an important subject of the present invention to provide a heat dissipating module to solve above-mentioned problems and let the fan be rapidly and stably fixed onto the heat sink with no damage to the heat sink, and exempt from extra work to the heat sink and speedup the assembly.

### SUMMARY OF THE INVENTION

In view of the foregoing, the present invention is to provide a heat dissipating module with a plurality of holding elements and fixing elements to rapidly and stably fix a fan onto a heat sink for simplifying the assembly and saving manual cost.

To achieve the above, a heat dissipating module according to the present invention includes a heat sink, a fan, a plurality of holding elements and a plurality of fixing elements. The heat sink has a plurality parallel of fins extended outwards. The fan is disposed on the fins and has a plurality of fixing holes. The holding elements are respectively disposed on the two adjacent fins. The holding element includes a top portion and two side portions respectively extended toward to the heat sink from two corresponding sides of the top portion, and the top portion has at least one through hole. The fixing elements respectively thread through the fixing hole and the through hole and the side portions of the holding element. Thus, the fixing element and the respective holding element clamp the two adjacent fins, wherein the side portion of the holding element has a plurality of interference parts in at least one internal side.

As mentioned above, by disposing a plurality of holding elements and fixing elements to rapidly and stably fix a fan onto a heat sink, a heat dissipating module according to the present invention simplifies the assembly and saving manual cost.

### BRIEF DESCRIPTION OF THE DRAWINGS

The present invention will become more fully understood from the detailed description given herein below illustration only, and thus is not limitative of the present invention, and wherein:

FIG. 1 is a lateral composed view showing a conventional heat dissipating module;

FIG. 2 is a three-dimensional decomposed view showing a heat dissipating module according to the present invention;

FIG. 3 is a lateral composed view showing a heat dissipating module according to the present invention;

FIG. 3A is a partial lateral composed view showing another heat dissipating module according to the present invention; and

FIG. 4 is a three-dimensional decomposed view showing the other heat dissipating module according to the present invention.

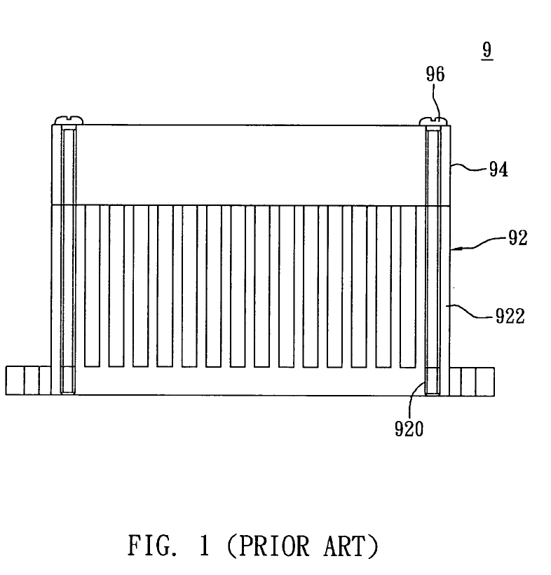

### DETAILED DESCRIPTION OF THE INVENTION

The present invention will be apparent from the following detailed description, which proceeds with reference to the accompanying drawings, wherein the same references relate to the same elements.

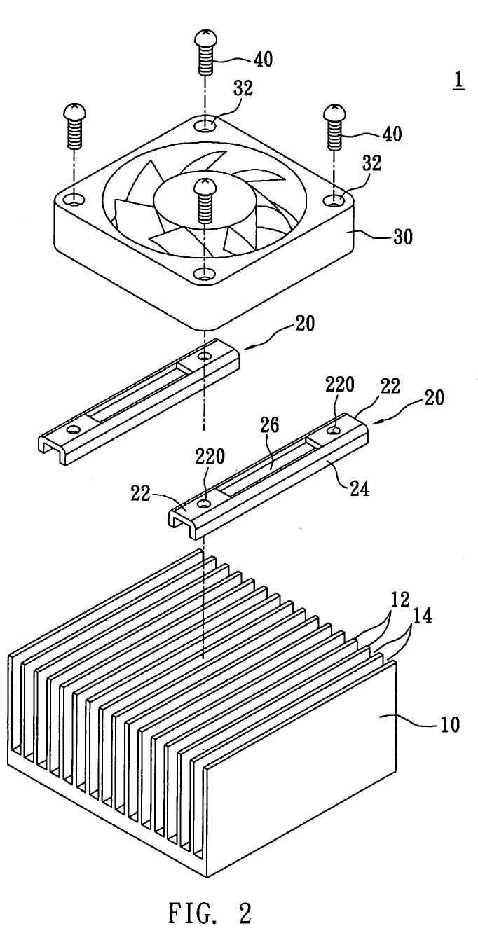

As shown in FIG. 2, a heat dissipating module 1 according to the present invention includes a heat sink 10, a plurality of holding elements 20, a fan 30 and a plurality of fixing elements 40.

The heat sink 10 has a plurality parallel of fins 12 extended outward. More particularly, the heat sink 10 has a bottom portion and a plurality of fins extended against the bottom portion. In this embodiment, the heat sink 10 is formed by extrusion molding with a distance 14 between two adjacent fins 12.

The holding elements 20 are respectively disposed on the two adjacent fins 12. The holding element 20 includes a top portion 22 and two side portions 24 respectively extended from two corresponding sides of the top portion 22, and the top portion 22 has at least one through hole 220. The diameter of the through hole 220 of the holding element 20 is slightly greater than the distance 14 between the two adjacent fins 12. In this embodiment, the length of the side portion 24 of the holding element 20 is slightly equal to that of the fin 12. The top portion 22 of the holding element 20 has a rectangular opening 26 at the inner zone for passing the rising air flow. Two through holes 220 are respectively disposed aside the opening 26 for reducing the amount of the holding element 20 within the heat dissipating module 1.

In this embodiment, the holding element 20 is formed by stamping metal sheet and is in a U shape after stamping. Fabrication by stamping is easy and cost effective. The thickness of the side portion 24 of the holding element 20 should be less than or equal to the distance 14 between the two adjacent fins 12. The interval between the side portions 24 of the holding element 20 is equal to the width of the two adjacent fins 12 plus the distance 14 between the two adjacent fins 12.

The fan 30 is disposed on the fins 12 and has a plurality of fixing holes 32. In this embodiment, the fan 30 has four fixing holes 32.

The fixing elements 40 respectively sequentially thread through the fixing hole 32 and the through hole 220 for fixing the fan 30 onto the heat sink 10. The amount of the fixing elements 40 is disposed corresponding to that of the fixing hole 32.

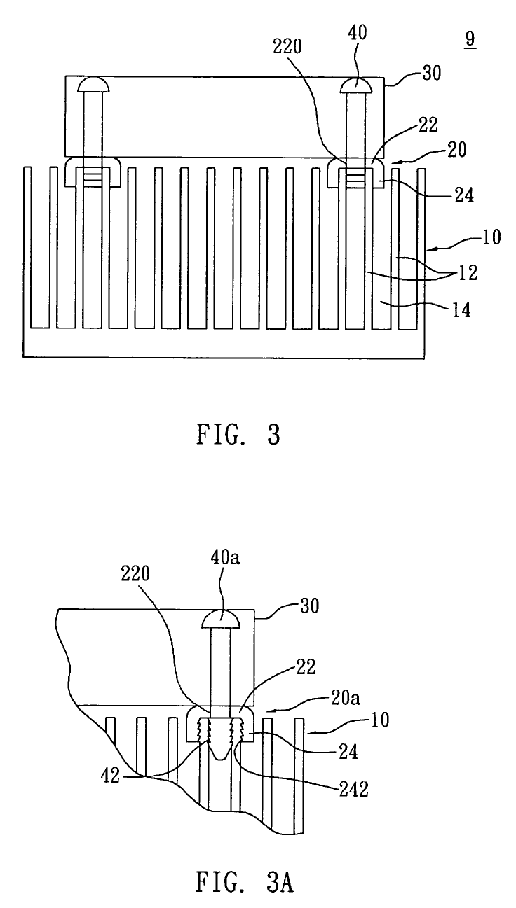

As shown in FIG. 3, the side portions 24 of the holding element 20 hold the fixing element 40 between the two adjacent fins 12 to avoid the fixing element 40 separating from the heat sink 10. In this embodiment, the fixing element 40 is a screw. The screw portion of the screw is slightly greater than the distance 14 between the two adjacent fins 12. The side portion 24 of the holding element 20 is interfered with the two adjacent fins 12 by the screw portion. One of the side portion 24 of the holding element 20 and the screw portion of the screws clamp a fin 12. Furthermore, the fixing element 40 may not be an ordinary screw. In a preferred embodiment, the fixing element 40 is higher than the fan 30. The height of the holding element 20 is at least equal to the protruding length of the fixing element 40 against the fan 30.

As shown in FIG. 3A, the internal side of the side portion 24 of another holding element 20a has a plurality of interference parts 242. The interference parts 242 can enhance the fixing between the holding element 20a and the heat sink 10.

Another fixing element 40a of the heat dissipating module 1 is a plug, like a screw bolt with no screw portion. The fixing element 40a has a plurality of barbs 42 lodged between the fins 12. Therefore, the fixing element 40a is directly pushed into the two adjacent fins 12 rather than screwing, then the fixing element 40a according to the present invention can simplify and speedup the assembly.

The holding element 20 of the heat dissipating module 1 according to the present invention can reduce the fabricating processes of the heat sink 10 and tight the fixing element 40 between the two adjacent fins 12 by interference for fixing the fan 30 onto the heat sink 10.

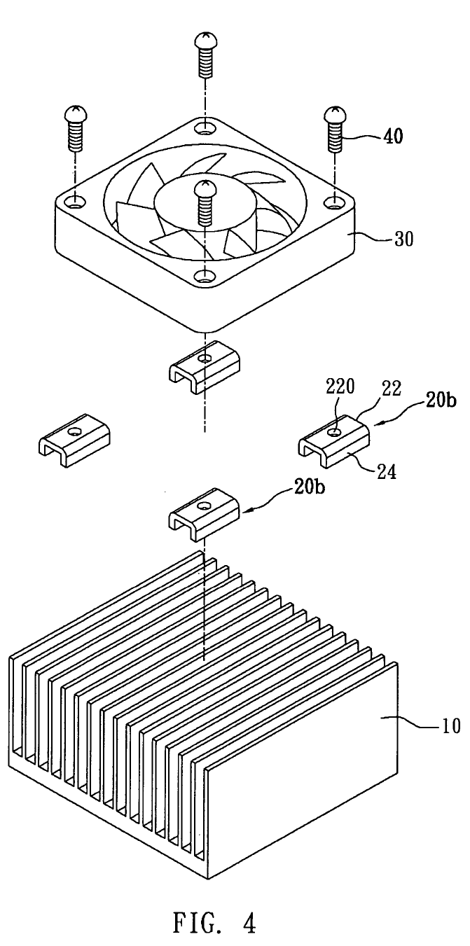

The holding element according to the present invention is not limitative to the embodiment disclosed herein above. As shown in FIG. 4, the other heat dissipating module according to the present invention provides a simplified holding element 20b. The holding element 20b includes a shorter top portion 22 and two side portions 24 respectively extended from two corresponding sides of the top portion 22, and the top portion 22 has only one through hole 220.

In summary, the present invention achieves excellent functions and results as follows:

1. By disposing a plurality of holding elements and fixing elements to rapidly and stably fix a fan onto a heat sink, a heat dissipating module according to the present invention avoids screw from sliding and loosing; and

2. The holding element according to the present invention is easy to make and simplifies the assembly, reduce the fabricating processes of the heat sink, and saving fabricating time and cost.

Although the present invention has been described with reference to specific embodiments, this description is not meant to be construed in a pivoting sense. Various modifications of the disclosed embodiments, as well as alternative embodiments, will be apparent to persons skilled in the art. It is, therefore, contemplated that the appended claims will cover all modifications that fall within the true scope of the present invention.

What is claimed is:

1. A heat dissipating module, comprising:
a heat sink having a plurality parallel of fins extended outward;
a fan disposed on the fins and the fan has a plurality of fixing holes;
a plurality of holding elements respectively disposed on the two adjacent fins, the holding element comprises a top portion and two side portions respectively extended toward to the heat sink from two corresponding sides of the top portion, and the top portion has at least one through hole; and
a plurality of fixing elements respectively threading through the fixing hole and the through holes of the holding elements, and the side portions of the holding element and the fixing element clamp the two adjacent fins, wherein the side portion of the holding element has a plurality of interference parts in at least one internal side.

2. The heat dissipating module according to claim 1, wherein the holding element is formed by stamping metal sheet.

3. The heat dissipating module according to claim 2, wherein the holding element is in a U shape after stamping.

4. The heat dissipating module according to claim 1, wherein a diameter of the through hole of the holding element is slightly greater than a distance between the two adjacent fins.

5. The heat dissipating module according to claim 1, wherein a height of the holding element is at least equal to a protruding length between a height of the fixing element and a height of the fan.

6. The heat dissipating module according to claim 1, wherein an interval between the side portions of the holding element is equal to the width of the two adjacent fins plus the distance between the two adjacent fins.

7. The heat dissipating module according to claim 1, wherein the top portion of the holding element has an opening at an inner zone and two through holes respectively disposed aside the opening.

8. The heat dissipating module according to claim 1, wherein the length of the side portion of the holding element is slightly equal to that of the fin.

9. The heat dissipating module according to claim 1, wherein the fixing element is a screw.

10. The heat dissipating module according to claim 1, wherein the fixing element is a screw bolt and has a plurality of barbs lodged between the fins.

11. The heat dissipating module according to claim 1, wherein the heat sink further comprises a bottom portion, the fins are extended against the bottom portion.
